(19) United States
(12) Patent Application Publication
(10) Pub. No.: US 2021/0398780 A1
(43) Pub. Date: Dec. 23, 2021

(54) METHOD ANDD APPARATUS FOR ATOMIC LAYER DEPOSITION OR CHEMICAL VAPOR DEPOSITION

(71) Applicant: Lam Research Corporation, Fremont, CA (US)

(72) Inventors: Adrien LAVOIE, Newberg, OR (US); Joseph R. ABEL, West Linn, OR (US); Douglas Walter AGNEW, Portland, OR (US); Ian John CURTIN, Portland, OR (US)

(21) Appl. No.: 17/297,766

(22) PCT Filed: Nov. 21, 2019
(86) PCT No.: PCT/US2019/062607

§ 371 Date: May 27, 2021

Related U.S. Application Data
(60) Provisional application No. 62/773,377, filed on Nov. 30, 2018.

(51) Int. Cl. H01J 37/32; H01L 21/02; C23C 16/455

(52) U.S. Cl. CPC H01J 37/32449; H01L 21/0228; C23C 16/45561; C23C 16/45542; H01L 21/02274

(57) ABSTRACT

An apparatus is provided comprising a process chamber, a precursor gas source, a reactant gas source, an inhibitor gas source, a passivation gas source, a gas, a switching manifold, and a controller. The switching manifold in a first position provides a fluid connection between the inhibitor gas source and the gas inlet, wherein the switching manifold in a second position provides a fluid connection between the precursor gas source and the gas inlet, wherein the switching manifold in a third position provides a fluid connection between the reactant gas source and the gas inlet, wherein the switching manifold in a fourth position provides a fluid connection between the passivation gas source and the gas inlet; and wherein the switching manifold prevents the gas inlet from being in fluid connection with at least two of the gas sources at a same time

### CROSS-REFERENCE TO RELATED APPLICATION

This application claims the benefit of priority of U.S. Application No. 62/773,377, filed Nov. 30, 2018, which is incorporated herein by reference for all purposes.

### BACKGROUND

The present disclosure relates to the formation of semiconductor devices. More specifically, the disclosure relates to the formation of semiconductor devices using atomic layer deposition or chemical vapor deposition.

### SUMMARY

To achieve the foregoing and in accordance with the purpose of the present disclosure, an apparatus is provided comprising a process chamber, a precursor gas source, a reactant gas source, an inhibitor gas source, a passivation gas source, a gas inlet in fluid connection with the process chamber, a switching manifold, and a controller controllably connected to the switching manifold. The switching manifold in a first position provides a fluid connection between the inhibitor gas source and the gas inlet, wherein the switching manifold in a second position provides a fluid connection between the precursor gas source and the gas inlet, wherein the switching manifold in a third position provides a fluid connection between the reactant gas source and the gas inlet, wherein the switching manifold in a fourth position provides a fluid connection between the passivation gas source and the gas inlet; and wherein the switching manifold prevents the gas inlet from being in fluid connection with at least two of the precursor gas source, the reactant gas source, the passivation gas source, and the inhibitor gas source at the same time

In another manifestation, a method for filling features in a substrate is provided. An inhibitor layer selectively deposited at a selected depth of the features. An atomic layer deposition process or a chemical vapor deposition process deposits a deposition layer within the features, wherein the deposition layer is selectively inhibited on parts of the features where the inhibitor layer is deposited.

In another manifestation, an apparatus comprising a process chamber, a chemical vapor deposition gas source, an inhibitor gas source, a passivation gas source, a gas inlet in fluid connection with the process chamber, a switching manifold, and a controller controllably connected to the switching manifold is provided. The switching manifold in a first position provides a fluid connection between the inhibitor gas source and the gas inlet, wherein the switching manifold in a second position provides a fluid connection between the chemical vapor deposition gas source and the gas inlet, wherein the switching manifold in a third position provides a fluid connection between the passivation gas source and the gas inlet; and wherein the switching manifold prevents the gas inlet from being in fluid connection with at least two of the chemical vapor deposition gas source, the passivation gas source, and the inhibitor gas source at a same time.

These and other features of the present disclosure will be described in more detail below in the detailed description of the disclosure and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a schematic view of an embodiment of an atomic layer deposition (ALD) system.

FIG. 2 is a schematic view of a computer system that may be used in practicing an embodiment.

FIG. 3 is a flow chart of an embodiment that uses the ALD system, shown in FIG. 1.

FIGS. 4A-F are schematic cross-sectional views of part of a stack processed according to an embodiment.

FIG. 5 is a more detailed flow chart of a step of depositing an inhibitor layer.

FIG. 6 is a schematic view of an embodiment of a chemical vapor deposition (CVD) system.

FIG. 7 is a high level flow chart of a process that uses the CVD system, shown in FIG. 6.

### DETAILED DESCRIPTION

The present disclosure will now be described in detail with reference to a few preferred embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well-known process steps and/or structures have not been described in detail in order to not unnecessarily obscure the present disclosure.

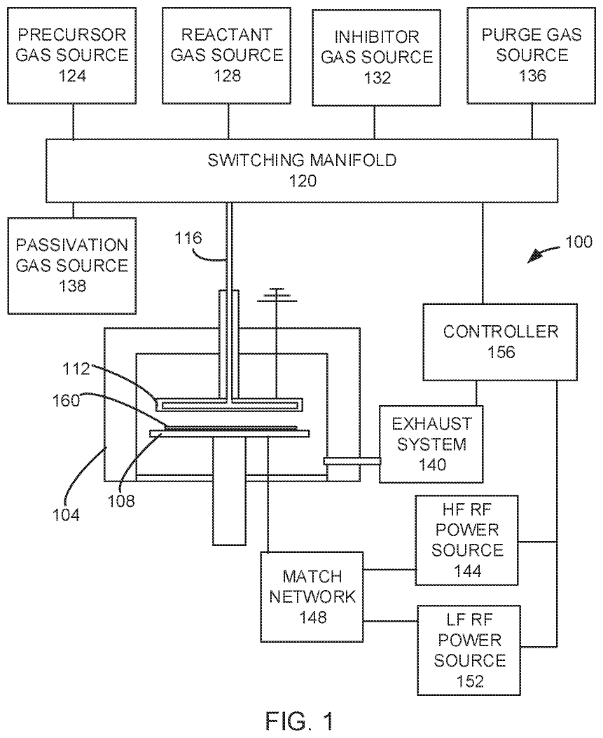

FIG. 1 is a schematic view of an embodiment of an atomic layer deposition (ALD) system 100. The ALD system 100 comprises a process chamber 104. Within the process chamber 104 is a substrate support 108. A showerhead 112 is positioned above the substrate support 108. A gas inlet 116 connects the showerhead 112 to a switching manifold 120. The switching manifold 120 is connected to a precursor gas source 124, a reactant gas source 128, an inhibitor gas source 132, a purge gas source 136, and a passivation gas source 138. The switching manifold 120 may comprise one or more manifolds connected to one or more valves. An exhaust system 140 is in fluid connection with the process chamber 104 to vent exhaust from the process chamber 104 and to control chamber pressure. A high frequency (HF) radio frequency RF source 144 is electrically connected through a match network 148 to the substrate support 108. A low frequency (LF) RF source 152 is electrically connected through the match network 148 to the substrate support 108. A controller 156 is controllably connected to the switching manifold 120, exhaust system 140, HF RF source 144, and LF RF source 152. A substrate 160 is placed on the substrate support 108. An example of such a chamber is the Striker™ Oxide system manufactured by Lam Research Corporation of Fremont, Calif.

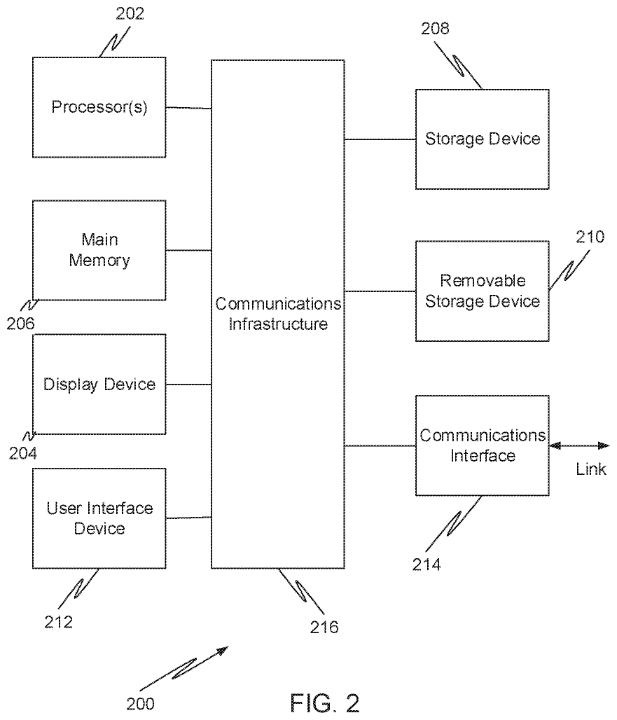

FIG. 2 is a high level block diagram showing a computer system 200, which is suitable for implementing a controller 156 used in embodiments. The computer system 200 may have many physical forms ranging from an integrated circuit, a printed circuit board, and a small handheld device up to a huge supercomputer. The computer system 200 includes one or more processors 202, and further can include an electronic display device 204 (for displaying graphics, text, and other data), a main memory 206 (e.g., random access memory (RAM)), storage device 208 (e.g., hard disk drive), removable storage device 210 (e.g., optical disk drive), user interface devices 212 (e.g., keyboards, touch screens, keypads, mice or other pointing devices, etc.), and a communications interface 214 (e.g., wireless network interface). The communications interface 214 allows software and data to be transferred between the computer system 200 and external devices via a link. The system may also include a communications infrastructure 216 (e.g., a communications bus, cross-over bar, or network) to which the aforementioned devices/modules are connected.

Information transferred via communications interface 214 may be in the form of signals such as electronic, electromagnetic, optical, or other signals capable of being received by communications interface 214, via a communication link that carries signals and may be implemented using wire or cable, fiber optics, a phone line, a cellular phone link, a radio frequency link, and/or other communication channels. With such a communications interface, it is contemplated that the one or more processors 202 might receive information from a network, or might output information to the network in the course of performing the above-described method steps. Furthermore, method embodiments may execute solely upon the processors or may execute over a network such as the Internet, in conjunction with remote processors that share a portion of the processing.

The term “non-transient computer readable medium” is used generally to refer to media such as main memory, secondary memory, removable storage, and storage devices, such as hard disks, flash memory, disk drive memory, CD-ROM, and other forms of persistent memory and shall not be construed to cover transitory subject matter, such as carrier waves or signals. Examples of computer code include machine code, such as produced by a compiler, and files containing higher-level code that are executed by a computer using an interpreter. Computer readable media may also be computer code transmitted by a computer data signal embodied in a carrier wave and representing a sequence of instructions that are executable by a processor.

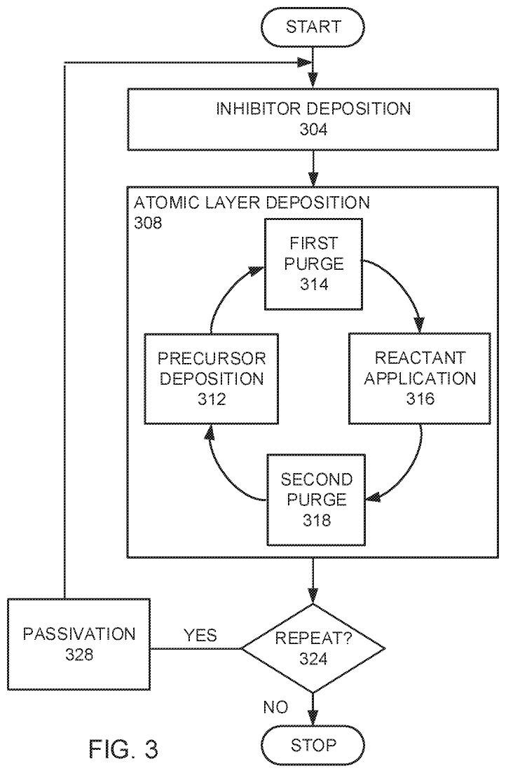

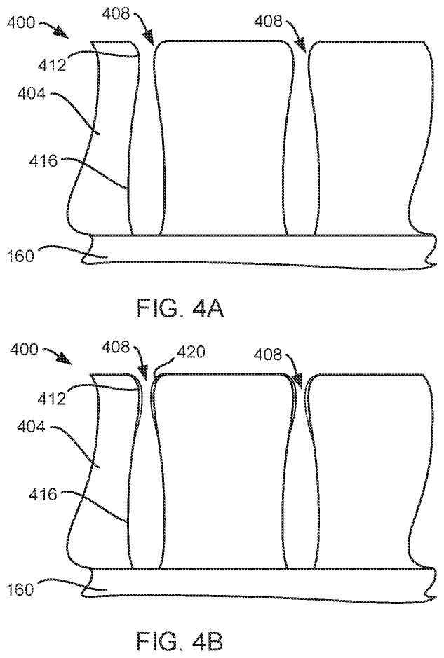

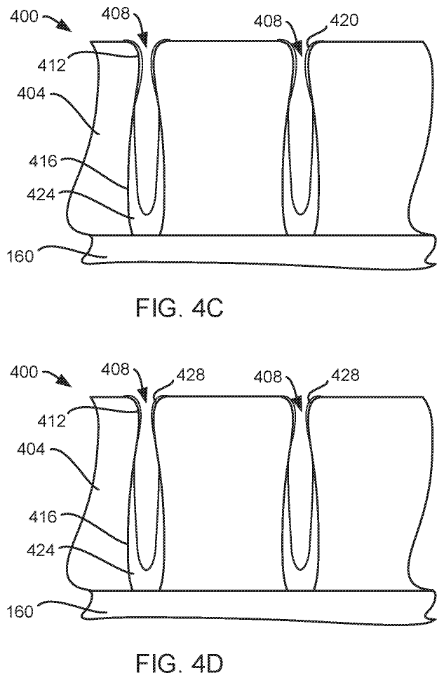

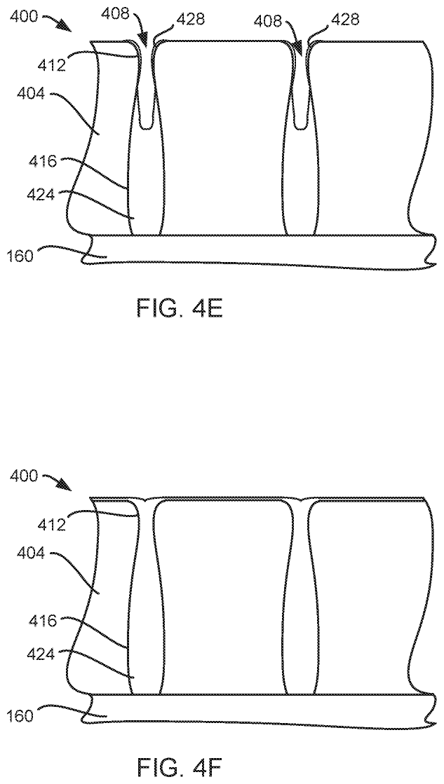

FIG. 3 is a high level flow chart of a process that uses the ALD system 100. The process may be called inhibition controlled enhancement (ICE). In an embodiment, a gap fill is provided to a substrate 160 on the substrate support 108. FIG. 4A is an enlarged cross-sectional view of part of a substrate 160 under a stack 400. A layer 404 over the substrate 160 has one or more features 408. The figures may not be drawn to scale. In this embodiment, the features are high aspect ratio features with a ratio of a depth to the largest width of greater than 50:1. In this example, the features 408 have a neck 412, where the features 408 become narrow. In addition, the features 408 at a location 416 bow, where the features 408 are widest. A conformal deposition would close the neck 412, before the location 416 of the bow is filled, forming a void, when the features are filled.

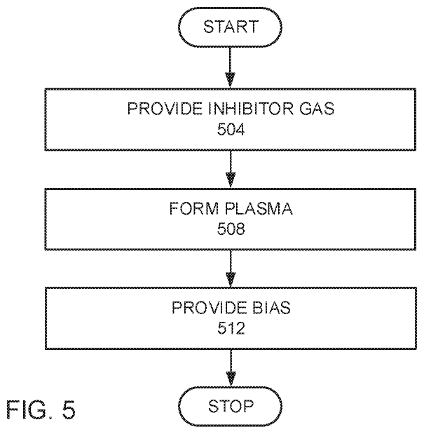

In this embodiment, an inhibitor deposition process is provided (step 304). FIG. 5 is a more detailed flow chart of the step of the inhibitor deposition process (step 304). An inhibitor gas is provided (step 504). The inhibitor gas is flowed into the process chamber 104. In this example, the switching manifold 120 is placed in a first position. In the first position of the switching manifold 120, the inhibitor gas source 132 is in fluid connection with the gas inlet 116. An inhibitor gas flows from the inhibitor gas source 132 through the gas inlet 116 into the process chamber 104. In the first position, the precursor gas source 124, the reactant gas source 128, the purge gas source 136, and the passivation gas source 138 are not in fluid connection with the gas inlet 116. In this example, the inhibitor gas is between 5 sccm to 1000 sccm of iodine. The inhibitor gas is formed into an inhibitor plasma (step 508). In this example, first a high-frequency excitation power is provided at a frequency of 13.56 megahertz (MHz) and a power of between 250 to 6500 watts. A bias is provided (step 512). In this example, a first low-frequency bias power is provided at a frequency of 400 kHz and a power of between 0 to 5000 watts. After between 0.05 to 500 seconds the inhibitor deposition process is stopped.

FIG. 4B is an enlarged cross-sectional view of part of a substrate 160 and stack 400 after the inhibitor is applied to form an inhibitor layer 420. The inhibitor layer 420 is mostly deposited in regions where deposition is to be depressed, such as the neck 412 to avoid pinching and forming a void. The high-frequency excitation power and the low-frequency bias may be used as a tuning knob to selectively deposit the inhibitor layer 420 at a selected depth so that the inhibitor layer is deposited on a desired part of the features 408. In addition, the length of time for applying the inhibitor may be used as an additional tuning knob.

After the inhibitor layer 420 has been deposited, an atomic layer deposition process is provided (step 308). In this example, the atomic layer deposition process (step 308) comprises a precursor deposition process (step 312), a first purge (step 314), a reactant application process (step 316), and a second purge (318). In this example, during the precursor deposition process (step 312) the switching manifold 120 is placed in the second position. In the second position of the switching manifold 120, the precursor gas source 124 is in fluid connection with the gas inlet 116. A precursor gas flows from the precursor gas source 124 through the gas inlet 116 into the process chamber 104. In the second position, the inhibitor gas source 132, the reactant gas source 128, and the purge gas source 136 are not in fluid connection with the gas inlet 116. In this example, the precursor gas is between 100 sccm to 1000 sccm of a silicon containing precursor, such as C₆H₁₉N₃Si. In this example, the precursor gas is not formed into a plasma. Therefore, a second high-frequency power is provided at a frequency of 13.56 MHz and a power of less than 500 watts. In this example, this power is 0 watts, so that no high-frequency power is provided. In this example, a low bias or no bias is provided. As a result, a second low-frequency bias power is provided at a frequency of 400 kHz and a power of less than 500 watts. After between 0.05 to 10 seconds the application of the precursor is stopped. In this example, the flow of the precursor gas is stopped.

When the flow of the precursor gas is stopped, a first purge of the precursor gas is provided (step 314) by placing the switching manifold 120 in a position so that the purge gas source 136 is in fluid connection with the gas inlet 116. A purge gas flows from the purge gas source 136 through the gas inlet 116 into the process chamber 104. The inhibitor gas source 132, the reactant gas source 128, and the precursor gas source 124 are not in fluid connection with the gas inlet 116. In this example, the purge gas may be Ar.

After the precursor gas is purged by providing the first purge (step 314), the reactant application is provided (step 316). A reactant gas is flowed into the process chamber 104. In this example, the switching manifold 120 is placed in a third position. In the third position of the switching manifold 120, the reactant gas source 128 is in fluid connection with the gas inlet 116. A reactant gas flows from the reactant gas source 128 through the gas inlet 116 into the process chamber 104. In the third position, the precursor gas source 124, the inhibitor gas source 132, and the purge gas source 136 are not in fluid connection with the gas inlet 116. In this example, the reactant gas is an oxidizing gas of between 250 sccm to 20000 sccm of oxygen (O₂). The reactant gas is formed into a plasma. In this example, a third high-frequency excitation power is provided at a frequency of 13.56 MHz and a power of between 125 to 6500 watts. A bias is provided (step 512). In this example, a third low-frequency bias power is provided at a frequency of 400 kHz and a power of between 25 to 5000 watts. After between 0.05 to 140 seconds the application of the reactant gas is stopped.

When the flow of the reactant gas is stopped, a second purge gas is provided (step 318) to purge the reactant gas. The second purge gas may be the same as the first purge gas or maybe a different purge gas. If the second purge gas is the same as the first purge gas, the second purge gas is provided by placing the switching manifold 120 in a position so that the purge gas source 136 is in fluid connection with the gas inlet 116. The second purge gas flows from the purge gas source 136 through the gas inlet 116 into the process chamber 104. The inhibitor gas source 132, the reactant gas source 128, and the precursor gas source 124 are not in fluid connection with the gas inlet 116. If the second purge gas is different than the first purge gas, the switching manifold is placed in a position so that another purge gas source is in fluid connection with the gas inlet 116.

The atomic layer deposition process (step 308) may be performed for one or more cycles. In this example, the atomic layer deposition process (step 308) is performed for 1 to 60 cycles. FIG. 4C is an enlarged cross-sectional view of part of a substrate 160 and stack 400 after the atomic layer deposition process (step 308) is completed. An atomic layer deposition 424 is shown to be larger than actual size in order to facilitate understanding. As shown, the atomic layer deposition 424 does not deposit or deposits less where the inhibitor layer 420 has been deposited. The inhibitor layer 420 selectively inhibits the atomic layer deposition on parts of the features where the inhibitor layer 420 is deposited.

In this example, the gap-fill is not complete, so the process is repeated (step 324). A passivation process (step 328) is provided to remove the remaining inhibitor layer 420. In this example, the switching manifold 120 is placed in a fourth position. In the fourth position of the switching manifold 120, the passivation gas source 138 is in fluid connection with the gas inlet 116. A passivation gas flows from the passivation gas source 138 through the gas inlet 116 into the process chamber 104. In the fourth position, the precursor gas source 124, the reactant gas source 128, the inhibitor gas source 132, and the purge gas source 136 are not in fluid connection with the gas inlet 116. In an embodiment, the passivation gas comprises oxygen. In other embodiments, the passivation gas may comprise one or more of O₂, H₂ or a noble gas, such as He or Ar. The passivation gas is formed into a plasma. In this example, a fourth high-frequency excitation power is provided at a frequency of 13.56 MHz and a power of between 250 to 6500 watts. A bias is provided. In this example, a fourth low-frequency bias power is provided at a frequency of 400 kHz and a power of between 0 to 5000 watts. The passivation process is then stopped. The passivation process selectively removes the remaining inhibitor deposition with respect to the atomic layer deposition 424.

A new inhibitor layer is deposited by providing another inhibitor deposition process (step 304). The inhibitor deposition process is repeated using a different HF RF power and LF RF power. FIG. 4D is an enlarged cross-sectional view of part of a substrate 160 and stack 400 after the inhibitor deposition process (step 304) is completed. In this example, the HF power and the LF power are adjusted so that the inhibitor layer 428 does not extend as far into the features 408 as the previous inhibitor layer 420. This allows atomic layer deposition to deposit further up the features 408.

The ALD process (step 308) is repeated. FIG. 4E is an enlarged cross-sectional view of part of the substrate 160 and stack 400 after the atomic layer deposition process (step 308) is completed. The atomic layer deposition 424 extends further up the features 408.

In some embodiments, the cycle of inhibitor deposition process (step 304) and atomic layer deposition process (step 308) and passivation process (step 328) are repeated between 1 and 2000 times. FIG. 4F is an enlarged cross-sectional view of part of the substrate 160 and stack after the gap fill process is complete. In this embodiment, the use of an inhibitor deposition and tuning of the LF RF signal power and HF RF signal power helps prevent voids in the gap fill. Additional processes may be performed on the stack 400.

The switching manifold 120 prevents any two of the inhibitor gas, precursor gas, purge gas, and reactant gas from flowing at the same time. Providing an inhibitor gas source 132 and a switching manifold 120 that provides inhibitor gas separately from the precursor gas and reactant gas, allows for an inhibitor deposition. In various embodiments, the inhibitor gas may be iodine, chlorine, nitrogen trifluoride (NF₃), Sulfonyl halides, diols (i.e. ethanediol, ethylene glycol, propanediol, etc.), diamines (i.e. ethylenediamine, propylenediamine, etc.), acetylene or ethylene, carbon monoxide (CO), carbon dioxide (CO₂), pyridine, piperidine, pyrrole, pyrimidine, imidazole, or benzene. In addition, the low-frequency RF and high-frequency RF configuration allow for tuning of the location of the inhibitor deposition, so that the inhibitor deposition is deposited in regions of the features where deposition is desired to be inhibited. The switching manifold 120 prevents the gas inlet 116 from being in fluid connection with at least two of the precursor gas source 136, the reactant gas source 128, the passivation gas source 138, the purge gas source 136, and the inhibitor gas source 132 at the same time. In this embodiment, when the switching manifold 120 is placed in a fifth position, the fifth position provides a fluid connection between the purge gas source 136 and the gas inlet 116 and prevents the gas inlet 116 from being in fluid connection with the precursor gas source 124, the reactant gas source 238, the passivation gas source 248, and the inhibitor gas source 132.

It has been found that by grounding the showerhead 112 and providing HF RF power and LF RF power to the substrate support 108, control of the location of the inhibitor deposition is improved. Without being bound by theory, it is believed that an increased bias on the substrate support causes deeper deposition of the inhibitor layer 420. In these embodiments low frequency is in the range of 100 kHz and 1 MHz. High frequency is in the range of 10 MHz and 100 MHz. Therefore, a selective bias may be used to control the selective deposition of the depth of the inhibitor layer 420.

Providing an inhibitor layer 420 that may be used for a plurality of atomic layer deposition cycles and using a passivation process to remove remaining inhibitor layer 420, before providing a new inhibitor layer 428, provides an improved tuning process. Therefore, providing a passivation gas separately from providing a precursor gas, providing a purge gas, providing a reactant gas and providing an inhibitor gas provides an improved ALD process.

In the above embodiment, a dielectric material, such as silicon oxide, is deposited in the gap-fill process. In other embodiments, other materials such as metal oxides are deposited in the gap-fill process.

In an embodiment, an acceleration controlled enhancement (ACE) may be provided to enable accelerated deposition on different regions of the features than where the inhibitor deposition is provided. The acceleration deposition would accelerate deposition at the regions where the acceleration deposition is deposited.

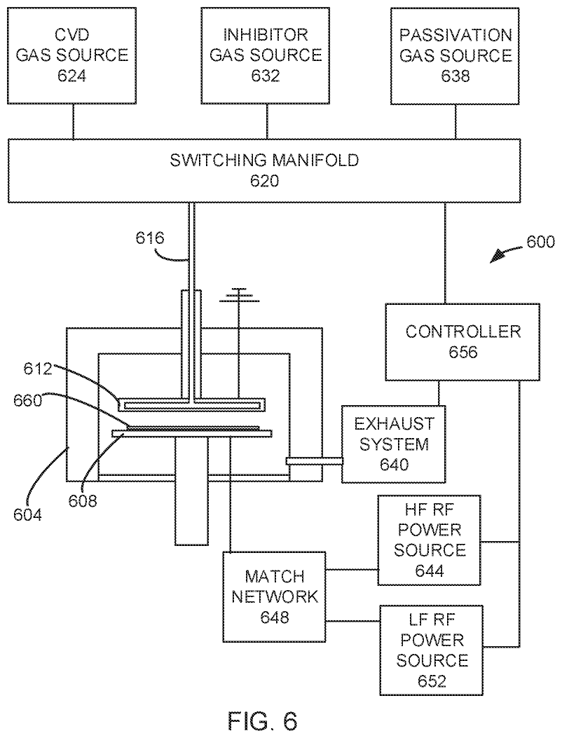

FIG. 6 is a schematic view of an embodiment of a chemical vapor deposition (CVD) system 600. The CVD system 600 comprises a process chamber 604. Within the process chamber 604 is a substrate support 608. A showerhead 612 is positioned above the substrate support 608. The showerhead 612 is grounded. A gas inlet 616 connects the showerhead 612 to a switching manifold 620. The switching manifold 620 is connected to a CVD gas source 624, an inhibitor gas source 632, and a passivation gas source 638. The CVD gas source 624 may comprise one or more gas sources used for the CVD process. The switching manifold 620 may comprise one or more manifolds connected to one or more valves. An exhaust system 640 is in fluid connection with the process chamber 604 to vent exhaust from the process chamber 604 and to control chamber pressure. A high frequency (HF) radio frequency RF source 644 is electrically connected through a match network 648 to the substrate support 608. In this embodiment, the HF RF source 644 provides an RF signal with a frequency in the range of 10 MHz to 100 MHz to the substrate support 608. A low frequency (LF) RF source 652 is electrically connected through the match network 648 to the substrate support 608. In this embodiment, the LF source 652 provides an RF signal with a frequency in the range of 100 kHz to 1 MHz. A controller 656 is controllably connected to the switching manifold 620, exhaust system 640, HF RF source 644, and LF RF source 652. A substrate 660 is placed on the substrate support 608

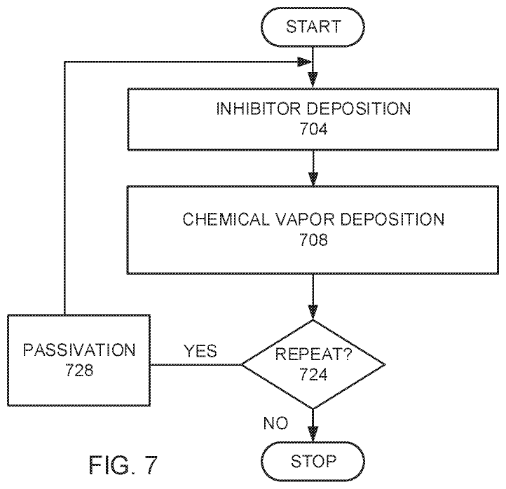

FIG. 7 is a high level flow chart of a process that uses the CVD system 600. The process may be called an inhibition controlled enhancement (ICE). In an embodiment, a gap fill is provided to a substrate 660 on the substrate support 608. An inhibitor deposition is provided (step 704). In this example, the inhibitor layer is deposited at the narrowest parts of the features. A chemical vapor deposition deposits a chemical vapor deposition layer (step 708). In this embodiment, the inhibitor deposition causes the chemical vapor deposition layer to selectively deposit less on regions of the features with the inhibitor layer than on regions of the features without the inhibition layer.

If the features are not completely filled, the process may be repeated (step 724). In this embodiment, a passivation step (step 728) is used to remove the remaining inhibitor layer. Another inhibitor deposition is provided (step 704) to deposit another inhibitor layer. Another CVD process is provided (step 708) to continue filling the features, where the CVD process selectively deposits lower on the regions with the inhibitor layer.

The switching manifold 620 in a first position provides a fluid connection between the inhibitor gas source 632 and the gas inlet 616, wherein the switching manifold 620 in a second position provides a fluid connection between the chemical vapor deposition gas source 624 and the gas inlet 616, wherein the switching manifold in a third position provides a fluid connection between the passivation gas source 638 and the gas inlet 616; and wherein the switching manifold 620 prevents the gas inlet 616 from being in fluid connection with at least two of the chemical vapor deposition gas source 624, the passivation gas source 638, and the inhibitor gas source 632 at the same time.

In this embodiment, the controller 656 comprises at least one processor and computer readable media. The computer readable media comprises computer code for providing a plurality of cycles, wherein each cycle comprises providing an inhibitor deposition, comprising placing the switching manifold 620 in the first position, and providing a chemical vapor deposition comprising placing the switching manifold 620 in the second position, and computer code for providing a passivation comprising placing the switching manifold 620 in a third position. In this embodiment, the controller 656 is controllably connected to the high-frequency RF source 644 and the low-frequency RF source 652. The computer readable media further comprises: computer code for providing a first high frequency excitation power and a first low frequency bias power when the switching manifold 620 is placed in the first position, computer code for providing a second high frequency excitation power and a second low frequency bias power when the switching manifold 620 is placed in the second position, and computer code for providing a third high frequency excitation power and a third low frequency bias power when the switching manifold 620 is placed in the third position. In this embodiment, the computer readable media further comprises computer code for providing a first high-frequency excitation power when the switching manifold 620 is placed in the first position, wherein the first high-frequency excitation power is greater than 250 watts.

While this disclosure has been described in terms of several preferred embodiments, there are alterations, modifications, permutations, and various substitute equivalents, which fall within the scope of this disclosure. It should also be noted that there are many alternative ways of implementing the methods and apparatuses of the present disclosure. It is therefore intended that the following appended claims be interpreted as including all such alterations, modifications, permutations, and various substitute equivalents as fall within the true spirit and scope of the present disclosure.

1. An apparatus, comprising:
a process chamber;
a precursor gas source;
a reactant gas source;
an inhibitor gas source;
a passivation gas source;
a gas inlet, in fluid connection with the process chamber;
a switching manifold, wherein the switching manifold in a first position provides a fluid connection between the inhibitor gas source and the gas inlet, wherein the switching manifold in a second position provides a fluid connection between the precursor gas source and the gas inlet, wherein the switching manifold in a third position provides a fluid connection between the reactant gas source and the gas inlet, wherein the switching manifold in a fourth position provides a fluid connection between the passivation gas source and the gas inlet; and wherein the switching manifold prevents the gas inlet from being in fluid connection with at least two of the precursor gas source, the reactant gas source, the passivation gas source, and the inhibitor gas source at a same time; and
a controller controllably connected to the switching manifold.

2. The apparatus, as recited in claim 1, further comprising:
a substrate support within the process chamber; and
a showerhead within the process chamber in fluid connection with the gas inlet.

3. The apparatus, as recited in claim 2, wherein the showerhead is disposed above the substrate support and is grounded.

4. The apparatus, as recited in claim 3, further comprising:
a low-frequency RF source electrically connected to the substrate support, wherein the low-frequency RF source provides an RF signal with a frequency in a range of 100 kHz to 1 MHz to the substrate support; and
a high-frequency RF source electrically connected to the substrate support, wherein the high-frequency RF source provides an RF signal with a frequency in a range of 10 MHz to 100 MHz to the substrate support.

5. The apparatus, as recited in claim 4, wherein the controller comprises:
at least one processor; and
computer readable media, comprising:
computer code for providing a plurality of cycles, wherein each cycle comprises:
providing an inhibitor deposition, comprising placing the switching manifold in the first position; and
providing at least one atomic layer deposition cycle, comprising:
placing the switching manifold in the second position; and
placing the switching manifold in the third position.

6. The apparatus, as recited in claim 5, wherein the controller is controllably connected to the high-frequency RF source and the low-frequency RF source, wherein the computer readable media, further comprises:
computer code for providing a first high-frequency excitation power when the switching manifold is placed in the first position;
computer code for providing a first low-frequency bias power when the switching manifold is placed in the first position;
computer code for providing a second high-frequency excitation power when the switching manifold is placed in the second position;
computer code for providing a second low-frequency bias power when the switching manifold is placed in the second position; and
computer code for providing a third high-frequency excitation power when the switching manifold is placed in the third position; and
computer code for providing a third low-frequency bias power when the switching manifold is placed in the third position.

7. The apparatus, as recited in claim 6, wherein the second high-frequency excitation power is less than 500 watts, and the second low-frequency bias power is less than 500 watts, the third high-frequency excitation power is greater than 125 watts, and the third low-frequency bias power is greater than 25 watts.

8. The apparatus, as recited in claim 7, wherein the first high-frequency excitation power is greater than 250 watts.

9. The apparatus, as recited in claim 8, wherein the computer code for providing a plurality of cycles, further comprises placing the switching manifold in a fourth position and wherein the computer readable media further comprises computer code for providing a fourth high-frequency excitation power when the switching manifold is placed in the fourth position, wherein the fourth high-frequency excitation power is greater than 250 watts.

10. The apparatus, as recited in claim 1, wherein the precursor gas source provides a silicon containing precursor and the reactant gas source provides an oxidizing gas.

11. The apparatus, as recited in claim 1, further comprising a purge gas source in fluid connection with the switching manifold, wherein in the first position, the second position, the third position, and the fourth position, the switching manifold prevents the purge gas source from being in fluid connection with the gas inlet, and wherein the switching manifold has a fifth position, wherein the fifth position provides a fluid connection between the purge gas source and the gas inlet and prevents the gas inlet from being in fluid connection with the precursor gas source, the reactant gas source, the passivation gas source, and the inhibitor gas source.

12. A method for filling features in a substrate, comprising:
a) selectively depositing an inhibitor layer at a selected depth of the features; and
b) providing an atomic layer deposition process or a chemical vapor deposition process to deposit a deposition layer within the features, wherein the deposition layer is selectively inhibited on parts of the features where the inhibitor layer is deposited.

13. The method, as recited in claim 12, further comprising repeating steps a and b.

14. The method, as recited in claim 12, further comprising after b then c) providing a passivation process, wherein the passivation process removes remaining inhibitor layer and then repeating steps a and b.

15. The method, as recited in claim 12, wherein the selectively depositing the inhibitor layer, comprises:
flowing an inhibitor gas;
transforming the inhibitor gas into an inhibitor plasma; and
stopping the flow of the inhibitor gas.

16. The method, as recited in claim 15, wherein the selectively depositing the inhibitor layer further comprises applying a selective bias.

17. An apparatus, comprising:
a process chamber;
a chemical vapor deposition gas source;
an inhibitor gas source;
a passivation gas source;
a gas inlet, in fluid connection with the process chamber;
a switching manifold, wherein the switching manifold in a first position provides a fluid connection between the inhibitor gas source and the gas inlet, wherein the switching manifold in a second position provides a fluid connection between the chemical vapor deposition gas source and the gas inlet, wherein the switching manifold in a third position provides a fluid connection between the passivation gas source and the gas inlet; and wherein the switching manifold prevents the gas inlet from being in fluid connection with at least two of the chemical vapor deposition gas source, the passivation gas source, and the inhibitor gas source at a same time; and
a controller controllably connected to the switching manifold.

18. The apparatus, as recited in claim 17, further comprising:
a substrate support within the process chamber; and
a showerhead within the process chamber in fluid connection with the gas inlet.

19. The apparatus, as recited in claim 18, wherein the showerhead is disposed above the substrate support and wherein the showerhead is grounded.

20. The apparatus, as recited in claim 19, further comprising:
a low-frequency RF source electrically connected to the substrate support, wherein the low-frequency RF source provides an RF signal with a frequency in a range of 100 kHz to 1 MHz to the substrate support; and
a high-frequency RF source electrically connected to the substrate support, wherein the high-frequency RF source provides an RF signal with a frequency in a range of 10 MHz to 100 MHz to the substrate support.

21. The apparatus, as recited in claim 20, wherein the controller comprises:
at least one processor; and
computer readable media, comprising:
computer code for providing a plurality of cycles, wherein each cycle comprises:
providing an inhibitor deposition, comprising placing the switching manifold in the first position;
providing a chemical vapor deposition comprising placing the switching manifold in the second position; and
providing a passivation comprising placing the switching manifold in a third position.

22. The apparatus, as recited in claim 21, wherein the controller is controllably connected to the high-frequency RF source and the low-frequency RF source, wherein the computer readable media, further comprises:
computer code for providing a first high-frequency excitation power when the switching manifold is placed in the first position;
computer code for providing a first low-frequency bias power when the switching manifold is placed in the first position;
computer code for providing a second high-frequency excitation power when the switching manifold is placed in the second position;
computer code for providing a second low-frequency bias power when the switching manifold is placed in the second position; and
computer code for providing a third high-frequency excitation power when the switching manifold is placed in the third position; and
computer code for providing a third low-frequency bias power when the switching manifold is placed in the third position.

23. The apparatus, as recited in claim 1, wherein the inhibitor gas source provides an inhibitor gas for forming an inhibitor layer, wherein the inhibitor layer inhibits the deposition of an atomic layer deposition, and wherein the passivation gas source provides a passivation gas for removing the inhibitor layer.

24. The apparatus, as recited in claim 23, wherein the precursor gas source provides a precursor gas and the reactant gas source provides a reactant gas, wherein the precursor gas and reactant gas provide the atomic layer deposition.

25. The apparatus, as recited in claim 1, wherein the inhibitor gas source provides an inhibitor gas comprising at least one of iodine, chlorine, nitrogen trifluoride (NF₃), Sulfonyl halides, diols, diamines, acetylene or ethylene, carbon monoxide (CO), carbon dioxide (CO₂), pyridine, piperidine, pyrrole, pyrimidine, imidazole, and benzene.

26. The apparatus, as recited in claim 2, further comprising a high-frequency RF source electrically connected to the substrate support, wherein the high-frequency RF source provides an RF signal with a frequency in a range of 10 MHz to 100 MHz to the substrate support.

27. The method, as recited in claim 12, further comprising providing a passivation gas to tune the selectively depositing the inhibitor layer.

28. The method, as recited in claim 12, wherein the selectively depositing an inhibitor layer comprises providing an inhibitor gas comprising at least one of iodine, chlorine, nitrogen trifluoride (NF₃), Sulfonyl halides, diols, diamines, acetylene or ethylene, carbon monoxide (CO), carbon dioxide (CO₂), pyridine, piperidine, pyrrole, pyrimidine, imidazole, and benzene.

29. The apparatus, as recited in claim 13, wherein at step a a first bias is provided that causes the inhibitor layer to be deposited to a first depth into features and wherein when step a is repeated a second bias is created that causes the inhibitor layer to be deposited to a second depth into the features, wherein the first bias is greater than the second bias and wherein the first depth is greater than the second depth.

30. The method, as recited in claim 14, wherein the providing the passivation process comprises providing a passivation gas comprising at least one of O₂, H₂ and a noble gas.

31. The apparatus, as recited in claim 14, wherein at step a a first bias is provided that causes the inhibitor layer to be deposited to a first depth into features and wherein when step a is repeated a second bias is created that causes the inhibitor layer to be deposited to a second depth into the features, wherein the first bias is greater than the second bias and wherein the first depth is greater than the second depth.

32. The apparatus, as recited in claim 17, wherein the inhibitor gas source provides an inhibitor gas for forming an inhibitor layer, wherein the inhibitor layer inhibits the deposition of an atomic layer deposition, and wherein the passivation gas source provides a passivation gas for removing the inhibitor layer.

33. The apparatus, as recited in claim 32, wherein at step a a first bias is provided that causes the inhibitor layer to be deposited to a first depth into features and wherein when step a is repeated a second bias is created that causes the inhibitor layer to be deposited to a second depth into the features, wherein the first bias is greater than the second bias and wherein the first depth is greater than the second depth.

34. The apparatus, as recited in claim 18, further comprising a high-frequency RF source electrically connected to the substrate support, wherein the high-frequency RF source provides an RF signal with a frequency in a range of 10 MHz to 100 MHz to the substrate support.

35. An apparatus, comprising:
a process chamber;
a precursor gas source;
a reactant gas source;
an inhibitor gas source;
a passivation gas source;
a gas inlet, in fluid connection with the process chamber; and
a switching manifold, wherein the switching manifold in a first position provides a fluid connection between the inhibitor gas source and the gas inlet, wherein the switching manifold in a second position provides a fluid connection between the precursor gas source and the gas inlet, wherein the switching manifold in a third position provides a fluid connection between the reactant gas source and the gas inlet, wherein the switching manifold in a fourth position provides a fluid connection between the passivation gas source and the gas inlet; and wherein the switching manifold prevents the gas inlet from being in fluid connection with at least two of the precursor gas source, the reactant gas source, the passivation gas source, and the inhibitor gas source at a same time.
